(19) United States
(12) Patent Application Publication
(10) Pub. No.: US 2015/0024538 A1
(43) Pub. Date: Jan. 22, 2015

(54) VAPOR DISPENSING APPARATUS AND METHOD FOR SOLAR PANEL

(71) Applicant: TSMC Solar Ltd., Taichung City (TW)

(72) Inventor: Shih-Wei Chen, Kaohsiung City (TW)

(73) Assignee: TSMC Solar Ltd., Taichung City (TW)

(21) Appl. No.: 13/946,231

(22) Filed: Jul. 19, 2013

(51) Int. Cl. H01L 31/18; H01L 31/042

(52) U.S. Cl. CPC H01L 31/18; H01L 31/042
USPC 438/57; 118/715; 118/724

(57) ABSTRACT

An apparatus includes a manifold coupled to a vapor source, the manifold having a plurality of nozzles, an inner cylinder, and an outer cylinder containing the inner cylinder with a space defined between the inner and outer cylinders. One of the inner cylinder or outer cylinder is rotatable with respect to the other of the inner cylinder or outer cylinder. The outer cylinder has an inlet coupled to the manifold to receive vapor from the nozzles. The outer cylinder has an outlet for dispensing the vapor.

### FIELD

This disclosure relates to thin-film solar cell fabrication processes.

### BACKGROUND

Solar cells are photovoltaic components for direct generation of electrical current from sunlight. A number of solar cells are provided on a substrate that may be referred to as a solar cell substrate, a solar panel, or a solar module. The solar cell substrate captures energy from sunlight. Photons in sunlight hit the solar cells and are absorbed by an absorber layer comprising a material such as Cu(In,Ga,)Se2 (CIGS), (silicon, or other absorber materials. Negatively charged electrons are released from their atoms by the photons, causing an electric potential difference. Current starts flowing through the solar cell material to cancel the potential difference and this electricity is captured. The electricity produced by a multitude of solar cells on the solar cell substrate is harnessed and coupled to a power transmission medium (e.g., a cable).

Polycrystalline thin-film absorber films, such as CuInSe2 (CIS), Cu(In,Ga)Se2 (CIGS) and CdTe compound semiconductors, are important in photovoltaic solar cells because of their high efficiency, long-term stable performance and potential for low-cost production. In forming a CIGS absorber, successfully depositing the selenium is important, because the selenium flux dominates the final chalcopyrite phase formation and crystallization quality. For large scale deposition over an entire solar module or solar photovoltaic panel, the selenium uniformity can be difficult to maintain. Non-uniform selenium distribution effects the quality of the absorber layer.

### BRIEF DESCRIPTION OF THE DRAWINGS

FIG. 1 is a schematic diagram of a vapor deposition system for use in fabricating a photovoltaic solar cell, according to some embodiments of the present disclosure.

FIG. 2 shows the inner cylinder of FIG. 1.

FIG. 3 shows the outer cylinder of FIG. 1.

FIG. 4 shows a variation of the outer cylinder of FIG. 3.

FIGS. 5A and 5B show two examples of relative locations of the inlet and outlet shown in FIG. 1.

FIG. 6 shows the apparatus of FIG. 1, in a system having an endless conveyor.

FIG. 7 shows a variation of the system of FIG. 6, for depositing two different materials by vapor deposition.

FIG. 8 shows a carousel-type solar panel deposition system including the apparatus of FIG. 1

FIG. 9 shows an arrangement of plural vapor deposition apparatuses as shown in FIG. 1,

FIG. 10 is a flow chart of an embodiment of a method of using the apparatus of FIG. 1.

FIGS. 11A and 11B show a variation of the inner cylinder of FIG. 1.

FIG. 12 shows another variation of the inner cylinder of FIG. 1.

FIG. 13 is a plan view of an embodiment of a vapor distribution apparatus having a non-circular inner cylinder.

FIG. 14 is a diagram of an embodiment of a vapor distribution apparatus having two separate vapor sources.

FIG. 15 is a diagram of an embodiment of an inner cylinder having its own vapor source and distribution nozzles.

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

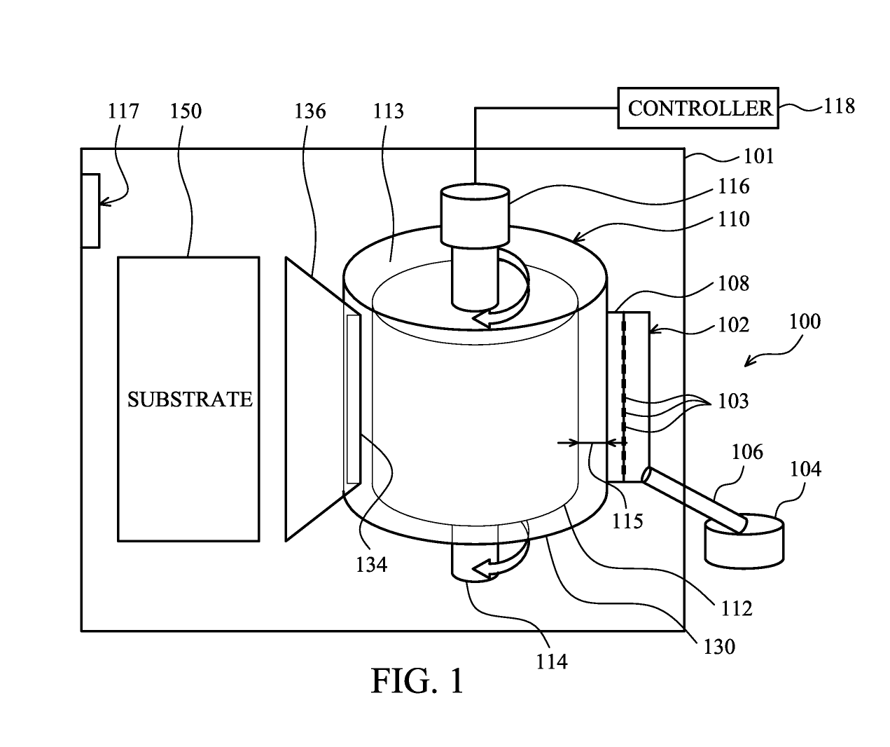

To improve solar photovoltaic panel thin film uniformity using vapor deposition, apparatus (110 in FIG. 1) is provided for making an uneven vapor distribution more homogenous. In some embodiments, the vapor is fed into a space 113 between two concentric circular cylinders 112, 130, and is emitted from an aperture or window 134 in another portion of the space 113. The configuration of the concentric cylinder assembly 110 is adapted to promote homogenization of the vapor density within the space 113.

FIG. 1 is a schematic elevation view of a vapor deposition apparatus 100. The apparatus 100 includes a chamber 101 configured to contain at least one manifold 102 having at least one dispensing nozzle 103, and at least one substrate 150 to be coated with the vapor dispensed from the nozzles 103. Although a cylindrical evaporation manifold 102 is shown, manifolds having other configurations (e.g., having one or more flat surfaces) can also be used.

In some embodiments, the substrate 150 is a thin film solar cell or a panel having a plurality of thin film solar cells. Such solar cells or panels 150 include a photovoltaic thin film which serves as light absorber material, formed over a substrate. Suitable materials for the underlying substrate include for example without limitation, glass (such as soda lime glass), ceramic, metals such as thin sheets of stainless steel and aluminum, or polymers such as polyamides, polyethylene terephthalates, polyethylene naphthalates, polymeric hydrocarbons, cellulosic polymers, polycarbonates, polyethers, combinations thereof, or the like. The absorber film is formed over substrate.

In some embodiments, the absorber material is copper indium gallium (di)selenide (CIGS), a I-III-VI2 semiconductor material composed of copper, indium, gallium, and selenium. CIGS is a solid solution of copper indium selenide (often abbreviated “CIS”) and copper gallium selenide. CIGS is a tetrahedrally bonded semiconductor, with the chalcopyrite crystal structure, and a bandgap varying continuously with x from about 1.0 eV (for copper indium selenide) to about 1.7 eV (for copper gallium selenide).

In an embodiment, the photovoltaic may comprise a p-type material. For example, the absorber layer can be a p-type chalcogenide material. In a further embodiment, the absorber layer can be a CIGS Cu(In,Ga)Se2 material. In other embodiments, chalcogenide materials including, but not limited to, Cu(In,Ga)(Se, S)2 or “CIGSS,” CuInSe2, CuGaSe2, CuInS2, and Cu(In,Ga)S2. can be used as an absorber layer material. Suitable p-type dopants that can be used for forming absorber layer include without limitation boron (B) or other elements of group II or III of the periodic table. In another embodiment, the absorber layer may comprise an n-type material including, without limitation, cadmium sulfide (CdS).

In other embodiments, the photovoltaic material is amorphous silicon (a-Si), protocrystalline, nanocrystalline (nc-Si or nc-Si:H), black silicon. or other thin-film silicon (TF-Si), Cadmium telluride (CdTe), or Dye-sensitized solar cell (DSC) or other organic solar cell material.

For example, in some embodiments, a back electrode comprising an initial molybdenum (Mo) bilayer is first sputtered onto a glass, metal foil or polymer substrate as the first electrode layer. A P1 microchannel is scribed in the Mo layer. Then the photovoltaic (absorber) layer described above is deposited over the Mo layer. In some embodiments, a sodium layer is deposited over the back electrode from an evaporation source. In some embodiments, one or more of the absorber CIGS precursors are deposited by co-evaporation from one or more evaporation sources 104 into the chamber 101. Then a buffer layer of CdS, AnS or InS is formed by sputtering, atomic layer deposition (ALD) or chemical-bath-deposition (CBD). The P2 microchannel is scribed. Then, the second electrode layer (e.g., a zinc oxide (i-ZnO) or Aluminum doped ZNO (AZO), boron-doped ZnO (BZO) is sputtered (or formed by Metal Organic Chemical Vapor Deposition, MOCVD) over the buffer layer. The P3 scribe line is then formed. In some embodiments, after the P3 scribing, the evaporation method can also be used to deposit an anti-reflective coating, such as magnesium fluoride (MgF2).

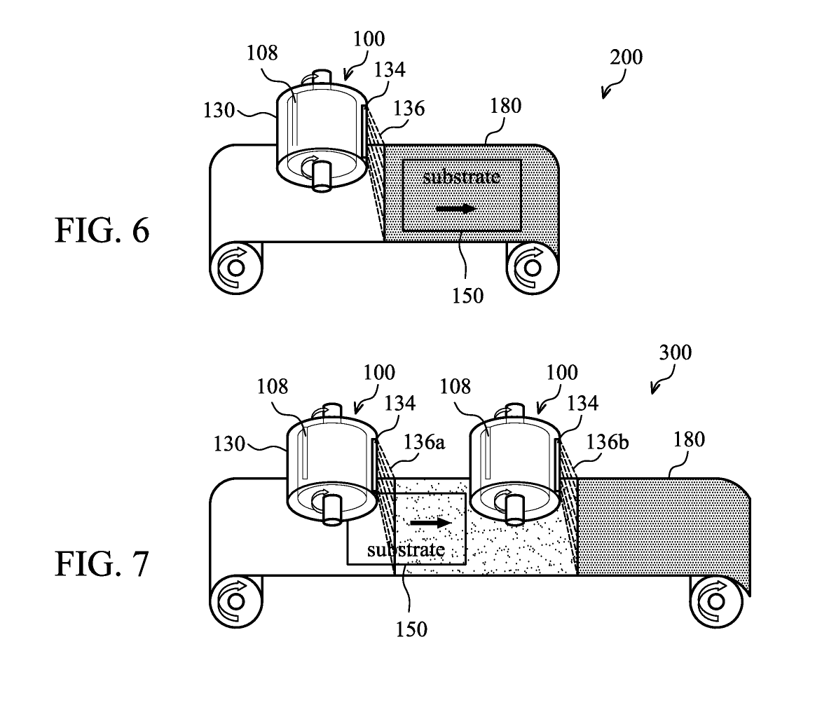

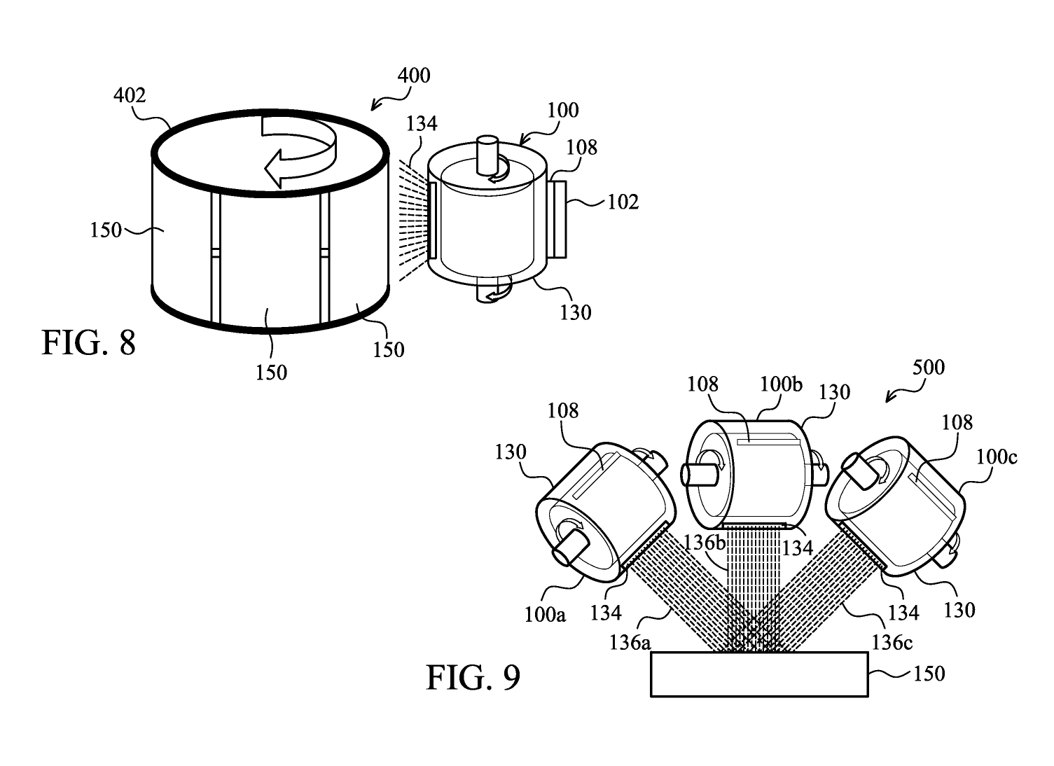

The chamber 101, in which the deposition takes place, is maintained under vacuum by a suitable vacuum pump (not shown). A vacuum port 117 is provided for evacuating air from the chamber 100. The apparatus 100 is suitable for processing substrates 150 which are larger in surface area than the cross section of the manifold 102 through which the material to be deposited passes. Thus, in the case of a large substrate, such as a solar panel, material is not deposited over the entire surface area of the substrate 150 simultaneously. In some embodiments, substrates 150 are carried through the chamber 101 on an endless conveyor 180 (FIGS. 6, 7). In other embodiments, substrates 150 are placed in batches on a carousel style apparatus (FIG. 8). In either type of deposition apparatus material is deposited on each region of the substrate 150 as that region passes a vapor spray 136.

In some embodiments, as shown in FIG. 1, the manifold 102 has a plurality of nozzles 103 for delivering a vapor across a line which corresponds to a width of the solar cell substrate. The width direction is normal to the motion of the conveyor 180 (or carousel 400), which conveys the substrate 150 past the manifold 102. In some embodiments, the diameter of nozzles 103 is from about 1.5 mm to about 3 mm, and the distance between nozzles 103 is from about 2.5 cm to about 3 cm.

The vapor is supplied from an evaporation source 104. In some embodiments, the evaporation source 104 includes a stainless steel tank, having an internal surface coated with titanium. The linear configuration of small nozzles 103 is referred to herein as a “line source” for brevity. In some embodiments, a controllable gas valve (not shown) is provided in the gas conduit 106 to control the vapor dispensing rate from the evaporation source 104.

A gas conduit 106 connects the manifold 102 to the evaporation source 104. In some embodiments, the conduit 106 has a heater (not shown) on or adjacent thereto, to heat the conduit to a temperature above the melting point of the vapor to be conveyed by the conduit.

In this description, discussion of seals and fastener hardware is omitted. One of ordinary skill in the art can readily apply these elements for sealing and joining the various vessels and conduits as appropriate.

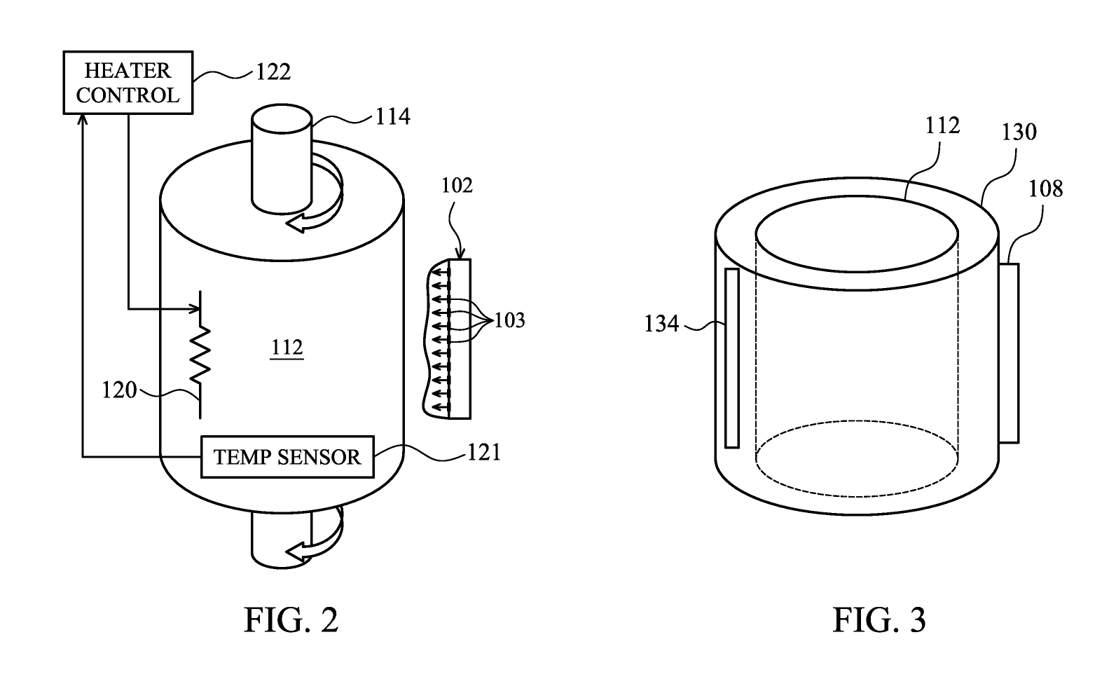

If the line source 102 is positioned so that the nozzles 103 spray directly on the solar panel substrate 150 to achieve large scale deposition, the uniformity (or non-uniformity) of flow rate between nozzles 103 can affect uniformity of the layer deposited. For a large scale spraying system, each nozzle 103 in manifold 102 displays a different spraying behavior due to different partial pressure distribution within the manifold. For example, if the vapor is fed into one end of the manifold, the pressure is generally greatest for nozzles near the supply end, and smallest for nozzles at the opposite end of the manifold. Further, partial clogging of one or more nozzles 103 over time can cause further deviations in flow, so that the density of vapor can vary non-linearly between the supply end of the manifold 102 and the opposite end, as shown in FIG. 2.

As shown in FIGS. 1-5B, a vapor distribution apparatus 110 includes a cylindrical redistribution vessel 130 having an inlet 108 coupled to the manifold 102 to receive vapor from the nozzles 103, and an outlet 134 for dispensing the vapor 136.

In some embodiments, the vapor distribution apparatus 110 includes an inner cylinder 112 and an outer cylinder 130 containing the inner cylinder, with a space 113 defined therebetween. In some embodiments, the inner cylinder 112 is rotatable with respect to the outer cylinder 130. The outer cylinder 130 has an inlet 108 coupled to the manifold 102 to receive vapor from the nozzles 103. The outer cylinder 130 has an outlet 134 for dispensing the vapor 136.

In some embodiments, the inner cylinder 112 and outer cylinder 130 comprise a material selected for its thermal resistive properties to avoid condensation of vapor. The inner cylinder 112 and outer cylinder 130 can comprise stainless steel, graphite composite, carbon composite, or other materials. In some embodiments, the inner cylinder 112 and outer cylinder 130 have a coating layer.

The inner cylinder 112 and outer cylinder 130 can be any size. In some embodiments, the height of the inner cylinder 112 and outer cylinder 130 is at least as large as the line source length. The size of the manifold 102 with nozzles 103 is a major factor in selecting the dimension of inner tank 112 and outer tank 130. For example, in one embodiment, the length of the manifold 102 is 60 cm; and the height of the inner cylinder 112 and outer cylinder 130 are 50 cm-70 cm.

As show in FIG. 1, the redistribution apparatus has a motor 116 coupled to rotate the inner cylinder or outer cylinder 112 about a longitudinal axis 114. The motor can be an AC motor, a DC brush motor or a DC stepper motor.

A controller 118 controls the operation of the motor to rotate the inner cylinder 112. The controller 118 can be implemented as an application in a processor (e.g., an embedded processor or external microcomputer) which controls the operation of the chamber 101.

The controller 118 controls the rotation of the inner cylinder to promote blending of the vapor and improve the uniformity of the density of the vapor within the space 113 between the inner and outer cylinders.

The processor 118 can control the rotation of the inner cylinder 112 to control whether the vapor flow in the space 113 between the inlet 108 and the outlet 134 is laminar flow or turbulent flow. Whether the flow is laminar or turbulent also depends on the spacing between the inner cylinder 112 and outer cylinder 130. A narrow spacing and/or lower rotation speed provides laminar flow with more homogeneous vapor behavior but will provide lower vapor flux 136 leaving the outlet 134 and deposited on the substrate 150. On the other hands, a wider spacing and/or faster rotation speed provides relative higher vapor flux. In some embodiments, a wide spacing and/or fast rotation speed results in turbulent flow.

The spacing 115 between inner cylinder 112 and outer cylinder 130 is generally fixed. Thus, a narrow spacing 115 between inner and outer cylinders 112, 130 is selected if laminar flow is generally desired, or a wider spacing 115 between inner and outer cylinders 112, 130 is selected if turbulent flow is generally desired. During operation the controller 118 adjusts the rotation speed, depending on which process or flux is desired.

If turbulent flow is desired, additional techniques are available to increase the turbulence of the flow. For example, a large temperature difference between the walls of inner cylinder 112 and outer cylinder 130 can cause turbulent flow. When the wall of inner cylinder 112 has a lower temperature than the wall of the outer cylinder 130, the vapor will tend to be more dense at the inner wall. This will help the molecular redistribution during rotation. In some embodiments, the temperatures of the inner cylinder 112 and outer cylinder 130 are both greater than the evaporation temperature of the material to be deposited. In some embodiments, the temperature of the inner cylinder 112 is the approximately the same as or slightly lower than the outer temperature.

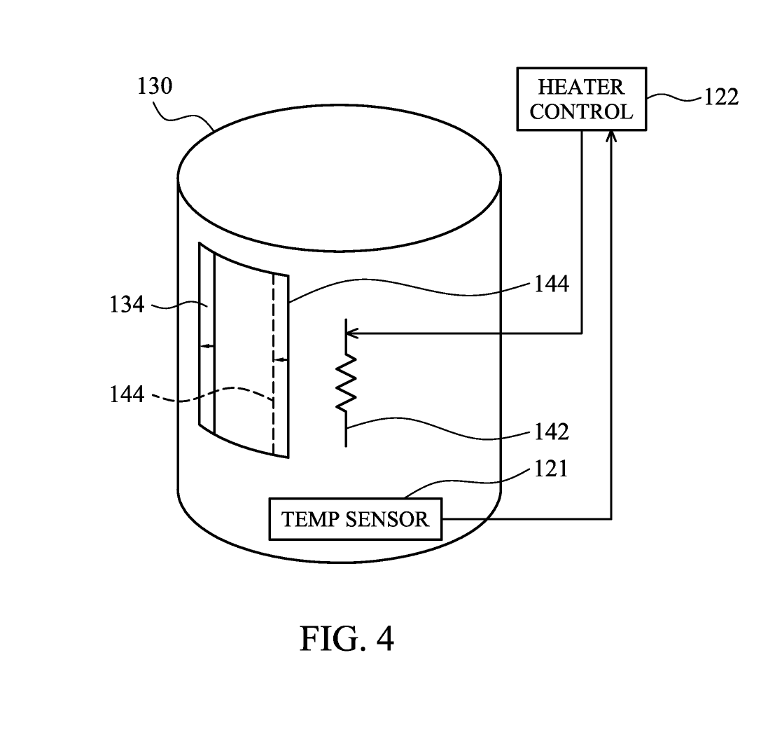

In some embodiments, at least one heater 120 (FIG. 2) is provided on the inner cylinder 112, for heating the inner cylinder. In some embodiments, at least one heater 142 (FIG. 4) is provided on the outer cylinder 130, for heating the outer cylinder. The heaters 120 and 142 are shown schematically. The heaters 120, 142 can have a variety of configurations for promoting uniform heating from the top of the space 113 to the bottom of the space 113. For example, in some embodiments, the heaters 120, 142 are configured to extend from the top of the space 113 to the bottom of the space. In some embodiments, the heaters 120 and/or 142 extend 360 degrees around the entire circumference of the inner cylinder 112 or the outer cylinder 130. In other embodiments, the heaters 120 and/or 142 extend part way around the circumference, for example, 90 or 180 degrees.

In some embodiments, a heater controller 122 is provided, for maintaining a temperature of the outer cylinder 130 greater than the temperature of the inner cylinder 112. A temperature sensor 121 senses the temperature of the surface of the cylinder(s) 112, 130, and provides temperature feedback signals to the heater controller 122. The heater controller 122 compares the sensed temperature to the setpoint and adjusts the current delivered to the heater 120, 142 accordingly. The temperature control can be a simple on/off control of the heaters, without or with hysteresis. In some embodiments, the current provided is proportional to the difference between the setpoint and the sensed temperature. In other embodiments, proportional-integral (PI), proportional derivative (PD) or proportional-integral-derivative (PID) control is used.

In some embodiments, a single heater control unit 122 controls the heaters 120, 142 (shown in FIGS. 2 and 4 respectively). For example, in some embodiments, for each type of material to be deposited, the heater control unit 122 has a respective predetermined setpoint temperature for each one of the inner cylinder heater 120 and the outer cylinder heater 142. For closed loop control, the temperatures of cylinders 112 and 130 are sensed during vapor deposition, and the heater control unit 122 controls supply of current to the heaters to maintain the temperatures at the setpoint. In some embodiments, the heater controller 122 also controls additional heaters (not shown) for controlling the temperature of the manifold 102 and its nozzles 103, as well as the vapor source 104.

In some embodiments, the heater control unit 122 is a programmed general purpose processor. In other embodiments, the heater control unit 122 is an embedded microcontroller or microprocessor, or a programmable logic controller (PLC).

In other embodiments, two separate heater control units (not shown) are provided for controlling the heaters 120 and 142, respectively.

In other embodiments, the heaters 120, 142 are controlled by the same processor 118 (FIG. 1) that operates the chamber.

In other embodiment, other means are provided for inducing turbulent flow in the space 113. For example, the surface of the inner cylinder 112 and/or outer cylinder 130 can be textured (e.g., ridged or knurled) to promote turbulence and improve blending.

In some embodiments, the outlet 134 is a fixed aperture (e.g., a rectangle) in the form of an elongated slot as shown in FIG. 3. The outlet 134 can be approximately the same size as the inlet 108, but the uniformity of the vapor density at the outlet 134 is greater than the uniformity of the density at the inlet 108.

In other embodiments, as shown in FIG. 4, the outlet 134 is an adjustable rectangular window. For example, a slidable plate 144 can partially cover a rectangular aperture. By sliding the plate left or right, the aspect ratio of the rectangular aperture can be adjusted. When the window is opened the aspect ratio of the outlet 134 decreases, and the vapor is provided over a larger area of the substrate 150 at any one time.

Although examples are shown in which the inner cylinder 112 rotates, and the outer cylinder 130 is stationary, in other embodiments (not shown), the outer cylinder 130 is rotatable with respect to the inner cylinder 112. Because the outlet 134 of the outer cylinder 130 faces the substrate in order to deposit material, the outer cylinder 130 is not rotated continuously for 360 degrees. For example, the outer cylinder can have a reciprocating rotational movement spanning a narrow angle, so that the outlet sweeps back and forth from one end of the substrate 150 to the other end of the substrate. In some embodiments, the reciprocating motion subtends an angle from about 30 degrees to about 120 degrees, depending on the distance between the outlet 134 and the substrate 150 and the length of the substrate 150. In embodiments having a reciprocating outer cylinder 130, the outer cylinder 130 is equipped with a stepper motor to provide precise reciprocating motion within a desired range.

In other embodiments, the inner cylinder 112 has a first motor for continuous rotation, and the outer cylinder 130 has a separate motor (not shown) for reciprocating motion.

The evaporation apparatus 100 of FIG. 1 is also suitable for depositing material onto other types and sizes of substrates, including but not limited to semiconductor wafers.

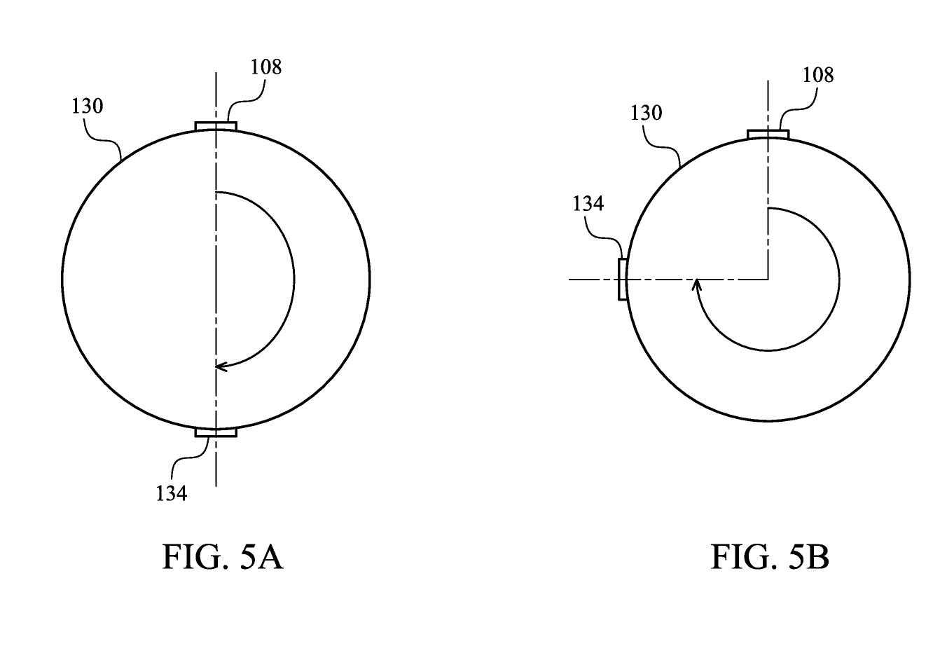

The outlet 134 is positioned at a distance from the inlet 108 expected to permit good blending between the inlet and outlet. For example, in some embodiments, as shown in FIG. 5A, the outlet 134 is about 180 degrees away from the outlet. In other embodiments, as shown in FIG. 5B, the outlet 134 is about 270 degrees away from the outlet. If the inner cylinder 112 is rotating slowly (e.g., to induce laminar flow), then a larger angle, as shown in FIG. 5B provides more blending between the inlet 112 and outlet 134. The pressure deviations within the space 113 reach a balance before the outlet 134.

The vapor distribution apparatus 110 can be included in vapor deposition systems having a variety of configurations.

FIGS. 6-8 show various means for holding a solar panel substrate 150 and moving the solar panel substrate past the outlet 134 of the vapor distribution apparatus 100. FIGS. 6 and 7 are schematic diagrams showing conveyor type systems 200 and 300 for vapor deposition on solar panel substrates. Other components (such as the chamber 101 are omitted from FIGS. 6 and 7 for clarity, but are understood to be present.

FIG. 6 shows an apparatus 200 having a single endless conveyor 180 and a single vapor distribution apparatus 100 for conveying a solar panel substrate 150 past the outlet 134 of the outer cylinder 130. In some embodiments, this apparatus can be used for continuously depositing vapor of a single material. In other embodiments, the apparatus of FIG. 6 can be used for sequentially applying vapor from plural different vapor sources 104. The flow of vapor of the first material is turned off, and the flow of the second material is turned on. If the apparatus is used to apply plural materials to the same substrate 150, the substrate can be returned from the right side of the conveyor to the left side without changing the conveyor direction, or the conveyor direction can be reversed for applying the second material.

FIG. 7 shows an apparatus 300 having a single endless conveyor 180 with plural vapor distribution apparatuses 100. Each apparatus 100 is connected to a respectively different vapor source 104 (not shown in FIG. 7). In some embodiments, each apparatus 100 has respective heater controllers 122. In other embodiments, a single heater controller 122 controls the heaters 120, 142, but each heater 120, 142 has its own setpoint temperature. The system 300 of FIG. 7 provides sequential deposition from the two vapor sources 104 without interrupting the motion of the conveyor 180 or interrupting the flow of vapor. Operation is simplified relative to the apparatus of FIG. 6, because the conveyor 180 of FIG. 7 can make a single pass to deposit both materials on substrate 150.

FIG. 8 shows a batch type apparatus 400 having a rotatable carousel 402 serving as the substrate holder configured to hold a solar panel substrate 150, and move the solar panel substrate 150 past the outlet 134 of the outer cylinder 130. In some embodiments, a single vapor distribution apparatus 100 is provided. In some embodiments, other stations (not shown) surrounding the carousel 400 can include additional vapor distribution apparatus 100 for simultaneously depositing one or more additional materials on one or more respective additional substrates. In some embodiments, other stations (not shown) surrounding the carousel 400 can perform other functions (e.g., sputtering).

FIG. 9 shows another arrangement 500 of three vapor distribution apparatus 100a-100c, for depositing three materials simultaneously on the same substrate 150. Alternatively, the three vapor distribution apparatus 100 can be spaced around the carousel 402 for simultaneously depositing three different materials on three different substrates.

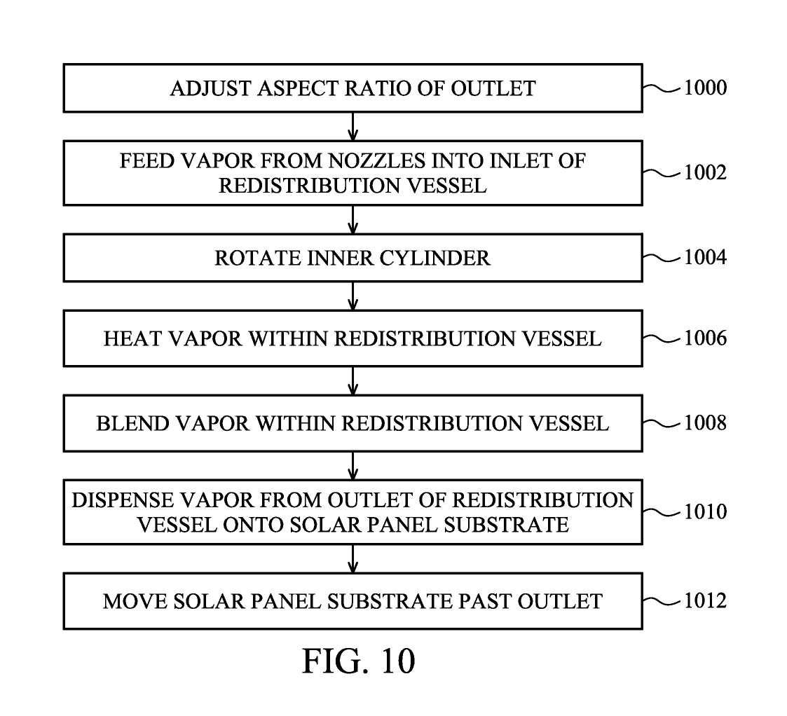

FIG. 10 is a flow chart of a method of vapor deposition, according to some embodiments. In one embodiment, the apparatus is used for depositing selenium from an evaporation source 104. Based on the melting points of selenium (221° C.) and sulfur (115° C.), and the boiling points of selenium (685° C.) and sulfur (444° C.), the temperature of the Se vapor source is maintained from about 300° C. to about 400° C. In some embodiments, the manifold 102 and nozzles 103 are maintained at respective temperatures from about 450° C. to about 550° C.

At step 1000, an aspect ratio of the window of outlet 134 is adjusted, so that the outlet 134 has a desired width. In some embodiments, the outlet 134 comprises an elongated window, and the adjusting includes sliding a plate 144 so as to partially cover or completely uncover the window. In some embodiments, the plate 144 is actuated to widen the window or make it narrower. In some embodiments, the adjustment is made manually. In other embodiments, an actuator (not shown) moves the plate 144. The processor 118 can control the repositioning of the plate 144 according to the type of material being deposited.

At step 1002 vapor is fed from a plurality of nozzles 103 of a manifold 102 into an inlet 108 of a redistribution vessel 110. The redistribution vessel has an outlet 134.

At step 1004, the inner cylinder is rotated.

At step 1006, at least one of the inner cylinder 112 or the outer cylinder 130 is heated, so as to heat the gas within a boundary layer close to the heated surface. In some embodiments, a temperature of the outer cylinder 130 is maintained hotter than a temperature of the inner cylinder 112.

At step 1008, the vapor is blended within the space 113 of the redistribution vessel 110, so that a density of the vapor at the outlet 134 is more uniform (from the top of the outlet 134 to the bottom of the outlet 134) than a density of the vapor at the inlet 108.

At step 1010, the vapor 136 is dispensed from the outlet 134 of the redistribution vessel 110 onto a solar panel substrate 150.

At step 1012, the solar panel substrate is moved past the outlet 134, where the outlet 134 comprises an elongated slot or window, oriented transversely to a direction of motion of the solar panel.

Although FIG. 10 shows the steps in one sequence, the sequence of FIG. 10 is not limiting, and the steps can be performed in other sequences. Also, some of the steps can be performed simultaneously. For example, in some embodiments, steps 1002-1012 are all performed simultaneously.

Although an example is described above in which the vapor distribution apparatus 100 is used for depositing selenium, the apparatus can be used for any vapor source, to improve the homogeneity of distribution. For example, the apparatus can be used for indium, gallium, sulfur, steam, metallic precursor in a Metal Oxide Chemical Vapor Deposition (MOCVD) process or the like.

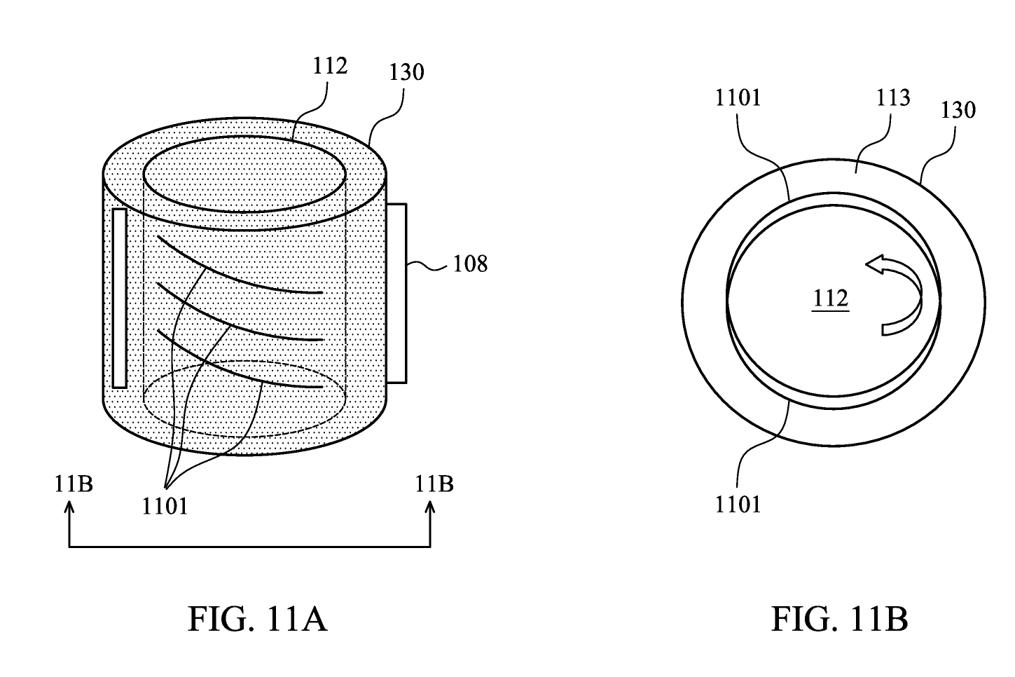

FIGS. 11A and 11B show a variation of the inner cylinder 112 of FIG. 1. In FIGS. 11A and 11B, a plurality of blades (vanes) 1101 are provided on the side surface of the inner cylinder 112 to promote blending. The blades can have a variety of shapes and sizes. Although FIG. 11A shows the blades all downwardly sloping and parallel to each other, the blades can be oriented with opposing slopes (e.g., an upwardly sloping blade and a downwardly sloping blade).

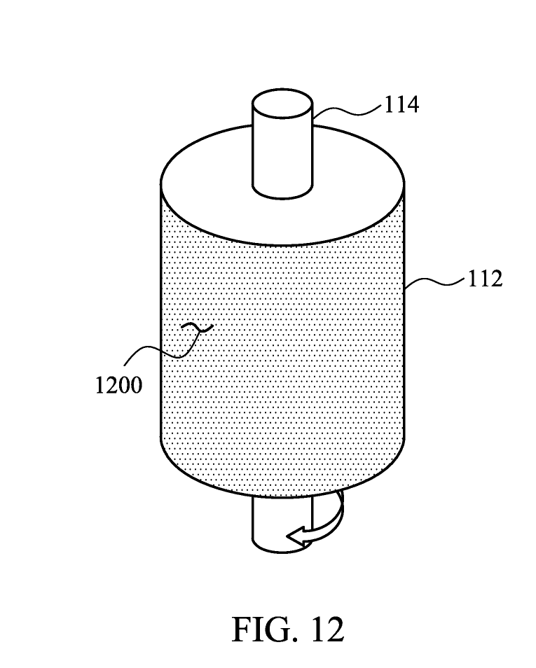

FIG. 12 shows another variation of the inner cylinder 112, in which the side surface 1200 of the inner cylinder 112 is textured, to promote turbulent flow and better blending. For example, in some embodiments, surface 1200 has ridges. In other embodiments, surface 1200 is knurled.

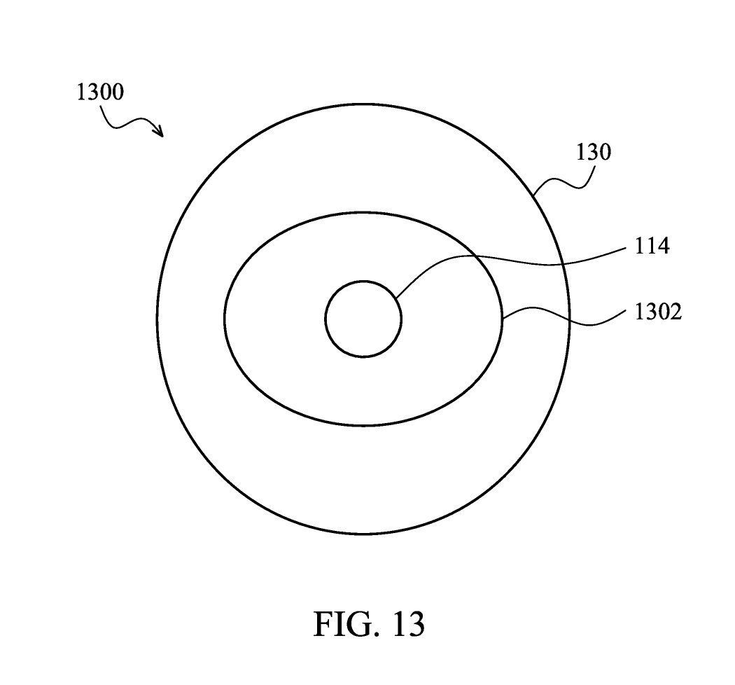

FIG. 13 is a plan view of an embodiment of a vapor distribution apparatus 1300 in which the inner cylinder 1302 has surface curvature variation, to promote blending of the vapor between the inner cylinder 1302 and the outer cylinder 130. In the example of FIG. 13, the inner cylinder 1400 is elliptical. In other embodiments (not shown), the inner cylinder can have an oval (egg-shaped) cross-section. In other embodiments (not shown), the curvature of the inner cylinder can vary in an irregular manner.

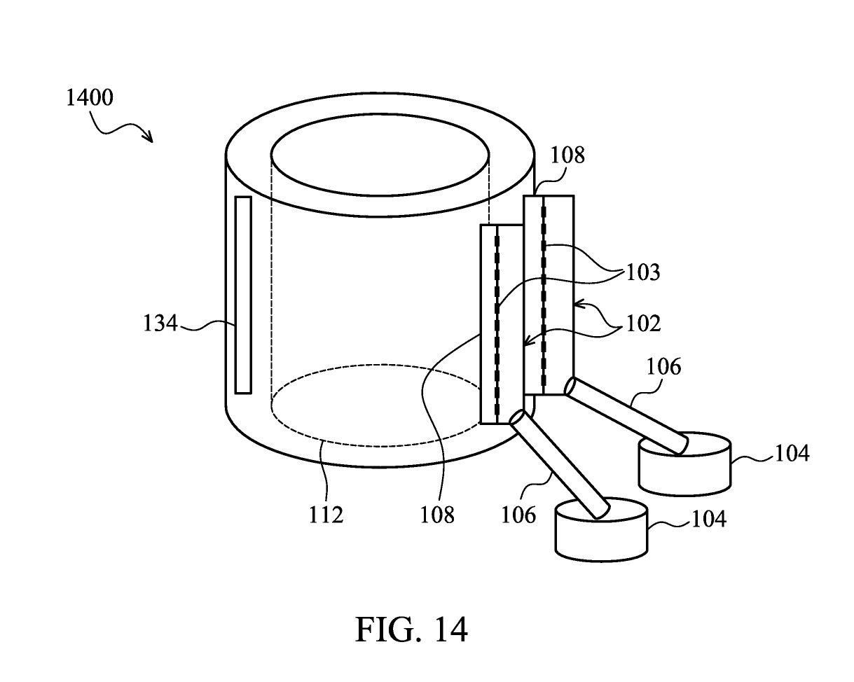

FIG. 14 shows another embodiment of a vapor distribution apparatus 1400, having two separate manifolds 102, each fed from a respective vapor source 104 by way of a respective conduit 106. Each manifold 102 has a respective set of dispensing nozzles 103. The apparatus 14 can be used for simultaneous blending and dispensing of two different materials from the vapor sources 104.

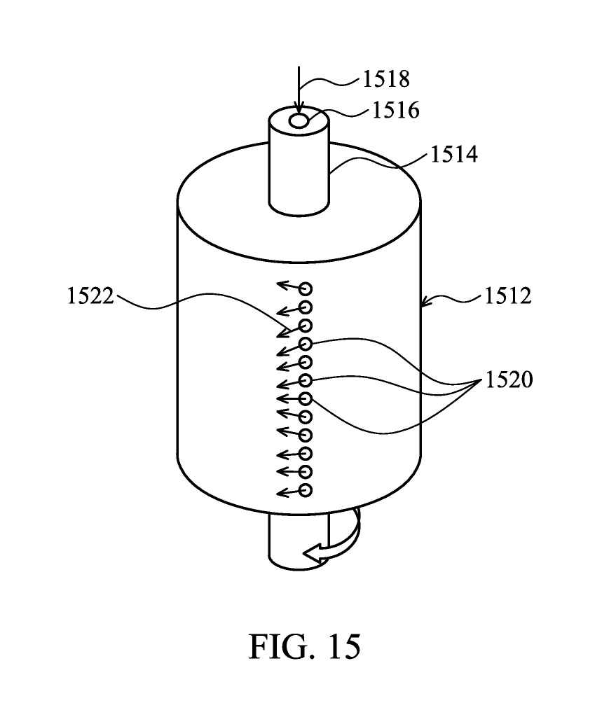

FIG. 15 shows another embodiment of the inner cylinder 1512 having its own separate vapor inlet 1516 and its own set of vapor distribution nozzles 1520. The vapor 1518 enters the vapor inlet 1516 and is distributed among the various nozzles 1520. The density of the distributed vapor 1622 from the nozzles 1520 closer to the inlet 1516 can be greater than the density of the vapor 1622 at the nozzles further from the inlet 1516. The relative rotation of the inner cylinder 1512 relative to the outer cylinder 130 promotes blending of the vapor, so that the density of the vapor leaving the window 134 of the outer cylinder 130 is more uniform than the density of the vapor leaving the nozzles 1520.

In some embodiments, the inner cylinder 1512 (with its own vapor inlet 1516) is substituted for the inner cylinder 112 in FIG. 1, to provide a second vapor source 1518. In some embodiments, the vapor source supplying vapor 1518 to vapor inlet 1516 of the inner cylinder 1512 dispenses a different material than the vapor source 104 that feeds the manifold 102 of the outer cylinder. This permits blending of multiple precursors in the space between the inner cylinder 1512 and the outer cylinder. In some embodiments, the inner cylinder 1512 of FIG. 15 is used with the outer cylinder 1400 of FIG. 14, permitting the blending of three different precursors. In other embodiments, the inner and outer cylinders dispense the same material.

In various embodiments, a vapor distribution apparatus can include any of the outer cylinder configurations shown in FIGS. 1, 4, 5A, 5B or 14, combined with any of the inner cylinder configurations shown in FIGS. 1, 11A and 11B, 12, 13 or 15, and can include any of the temperature controls shown in FIG. 2 or 4. Further any of these vapor distribution apparatuses can be included in any of the systems shown in FIG. 6, 7, 8 or 9. Various disclosed embodiments include all such combinations.

In some embodiments, an apparatus comprises a manifold coupled to a vapor source, the manifold having a plurality of nozzles, an inner cylinder, and an outer cylinder containing the inner cylinder with a space defined therebetween. One of the inner cylinder or outer cylinder is rotatable with respect to the other of the inner cylinder or outer cylinder. The outer cylinder has an inlet coupled to the manifold to receive vapor from the nozzles. The outer cylinder has an outlet for dispensing the vapor.

In some embodiments, the outlet is an elongated slot.

In some embodiments, the outlet is an adjustable rectangular window.

Some embodiments further comprise a motor coupled to rotate the inner cylinder or outer cylinder.

Some embodiments further comprise at least one heater for heating at least one of the inner cylinder or outer cylinder.

Some embodiments further comprise a heater controller, for maintaining a temperature of the outer cylinder greater than the temperature of the inner cylinder.

In some embodiments, the outlet is about 270 degrees away from the inlet.

In some embodiments, the inner cylinder is rotatable, and the outer cylinder is stationary.

Some embodiments further comprise a conveyor for conveying a solar panel substrate past the outlet of the outer cylinder.

Some embodiments further comprise a rotatable substrate holder configured to hold a solar panel substrate, and moving the solar panel substrate past the outlet of the outer cylinder.

In some embodiments, an apparatus comprises a manifold coupled to a vapor source, the manifold having a plurality of nozzles. A cylindrical redistribution vessel has an inlet coupled to the manifold to receive vapor from the nozzles, and an outlet for dispensing the vapor. Means are provided for holding a solar panel substrate and moving the solar panel substrate past the outlet.

In some embodiments, the redistribution vessel comprises: a rotatable inner cylinder; and a stationary outer cylinder containing the inner cylinder with a space defined therebetween. The outer cylinder includes the inlet and an adjustable rectangular window that constitutes the outlet. A motor IS coupled to rotate the inner cylinder.

Some embodiments further comprise at least one heater for heating at least one of the inner cylinder or outer cylinder; and a heater controller, for maintaining a temperature of the outer cylinder greater than the temperature of the inner cylinder.

In some embodiments, a method comprises feeding vapor from a plurality of nozzles of a manifold into an inlet of a redistribution vessel, the redistribution vessel having an outlet. The vapor is blended within the redistribution vessel, so that a density of the vapor at the outlet is more uniform than a density of the vapor at the inlet. The vapor is dispensed from the outlet of the redistribution vessel onto a solar panel substrate.

In some embodiments, the redistribution vessel includes a rotatable inner cylinder and an outer cylinder, with a space therebetween; the blending step is performed in the space; and the blending step includes rotating the inner cylinder.

In some embodiments, the redistribution vessel includes a rotatable inner cylinder and an outer cylinder, with a space therebetween; and the blending step is performed in the space. At least one of the inner cylinder or the outer cylinder is heated.

In some embodiments, the heating step includes maintaining a temperature of the outer cylinder hotter than a temperature of the inner cylinder.

Some embodiments further comprise adjusting an aspect ratio of the outlet.

In some embodiments, the outlet comprises an elongated window, and the adjusting includes sliding a plate so as to partially cover or completely uncover the window.

Some embodiments further comprise moving the solar panel substrate past the outlet, wherein the outlet comprises an elongated slot or window, oriented transversely to a direction of motion of the solar panel.

The methods and system described herein may be at least partially embodied in the form of computer-implemented processes and apparatus for practicing those processes. The disclosed methods may also be at least partially embodied in the form of tangible, non-transitory machine readable storage media encoded with computer program code. The media may include, for example, RAMs, ROMs, CD-ROMs, DVD-ROMs, BD-ROMs, hard disk drives, flash memories, or any other non-transitory machine-readable storage medium, wherein, when the computer program code is loaded into and executed by a computer, the computer becomes an apparatus for practicing the method. The methods may also be at least partially embodied in the form of a computer into which computer program code is loaded and/or executed, such that, the computer becomes a special purpose computer for practicing the methods. When implemented on a general-purpose processor, the computer program code segments configure the processor to create specific logic circuits. The methods may alternatively be at least partially embodied in a digital signal processor formed of application specific integrated circuits for performing the methods.

Although the subject matter has been described in terms of exemplary embodiments, it is not limited thereto. Rather, the appended claims should be construed broadly, to include other variants and embodiments, which may be made by those skilled in the art.

What is claimed is:

1. Apparatus comprising:
a manifold coupled to a vapor source, the manifold having a plurality of nozzles;
an inner cylinder; and
an outer cylinder containing the inner cylinder with a space defined therebetween, one of the inner cylinder or the outer cylinder being rotatable with respect to the other of the inner cylinder or outer cylinder, the outer cylinder having an inlet coupled to the manifold to receive vapor from the nozzles, the outer cylinder having an outlet for dispensing the vapor.

2. The apparatus of claim 1, wherein the outlet is an elongated slot.

3. The apparatus of claim 1, wherein the outlet is an adjustable rectangular window.

4. The apparatus of claim 1, further comprising a motor coupled to rotate the inner cylinder or outer cylinder.

5. The apparatus of claim 1, further comprising at least one heater for heating at least one of the inner cylinder or outer cylinder.

6. The apparatus of claim 5, further comprising a heater controller, for maintaining a temperature of the outer cylinder greater than the temperature of the inner cylinder.

7. The apparatus of claim 1, wherein the outlet is about 270 degrees away from the inlet.

8. The apparatus of claim 1, wherein the inner cylinder is rotatable, and the outer cylinder is stationary.

9. The apparatus of claim 1, further comprising a conveyor for conveying a solar panel substrate past the outlet of the outer cylinder.

10. The apparatus of claim 1, further comprising a rotatable substrate holder configured to hold a solar panel substrate, and moving the solar panel substrate past the outlet of the outer cylinder.

11. Apparatus comprising:
a manifold coupled to a vapor source, the manifold having a plurality of nozzles;
a cylindrical redistribution vessel having an inlet coupled to the manifold to receive vapor from the nozzles, and an outlet for dispensing the vapor, and
means for holding a solar panel substrate and moving the solar panel substrate past the outlet.

12. The apparatus of claim 11, wherein the redistribution vessel comprises:
a rotatable inner cylinder;
a stationary outer cylinder containing the inner cylinder with a space defined therebetween, the outer cylinder including the inlet and an adjustable rectangular window that constitutes the outlet; and
a motor coupled to rotate the inner cylinder.

13. The apparatus of claim 12, further comprising:
at least one heater for heating at least one of the inner cylinder or outer cylinder; and
a heater controller, for maintaining a temperature of the outer cylinder greater than the temperature of the inner cylinder.

14. A method, comprising:
feeding vapor from a plurality of nozzles of a manifold into an inlet of a redistribution vessel, the redistribution vessel having an outlet;
blending the vapor within the redistribution vessel, so that a density of the vapor at the outlet is more uniform than a density of the vapor at the inlet; and
dispensing the vapor from the outlet of the redistribution vessel onto a solar panel substrate.

15. The method of claim 14, wherein:
the redistribution vessel includes a rotatable inner cylinder and an outer cylinder, with a space therebetween;
the blending step is performed in the space; and
the blending step includes rotating the inner cylinder.

16. The method of claim 14, wherein:
the redistribution vessel includes a rotatable inner cylinder and an outer cylinder, with a space therebetween;
the blending step is performed in the space,
further comprising heating at least one of the inner cylinder or the outer cylinder.

17. The method of claim 16, wherein the heating step includes maintaining a temperature of the outer cylinder hotter than a temperature of the inner cylinder.

18. The method of claim 14, further comprising adjusting an aspect ratio of the outlet.

19. The method of claim 18, wherein the outlet comprises an elongated window, and the adjusting includes sliding a plate so as to partially cover or completely uncover the window.

20. The method of claim 18, further comprising moving the solar panel substrate past the outlet, wherein the outlet comprises an elongated slot or window, oriented transversely to a direction of motion of the solar panel.
